(19) United States
(12) Patent Application Publication
(10) Pub. No.: US 2005/0082613 A1
(43) Pub. Date: Apr. 21, 2005

(54) Semiconductor integrated circuit device and semiconductor memory using the same

(75) Inventor: Kazuo Taguchi, Chino-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/917,500

(22) Filed: Aug. 13, 2004

(30) Foreign Application Priority Data
Sep. 1, 2003 (JP) 2003-308255
Feb. 4, 2004 (JP) 2004-028121

(51) Int. Cl. H01L 27/12

(52) U.S. Cl. 257/347

(57) ABSTRACT

Aspects of the invention can provide a semiconductor device including a transistor having a gate shape, which enables a source area and a body contact area to be connected without using wiring and with no gate part protruding to the source area side, and a semiconductor memory. The semiconductor device can have field regions, a transistor which includes a gate (L type gate), a gate insulating film directly below the gate, a body area directly below the gate insulating film, and a source area and a drain area formed on both sides which hold the body area in between. The gate can consist essentially of a first part extending along a channel width direction on the field region and a second part protruding from one end of the first part in the channel width direction to the drain side, and being formed in the L type gate in a plan view. A body contact area can be provided on the field region on the opposite side to the first part with the second part of the L type gate in between, and a low resistant layer is formed on a surface between the source area and the body contact area.

### BACKGROUND OF THE INVENTION

1. Field of Invention

Aspects of the invention can relate to a semiconductor device that can have a transistor structure and an inverter structure formed on an SOI (silicon on Insulator) substrate and a semiconductor memory using the same.

2. Description of Related Art

As a shape of a gate on a field region of a transistor, in addition to a typically used I type gate for a bulk substrate, a T type gate can be used for securing a body contact on the SOI substrate. The I type gate has advantages of a small gate capacity and a minimum of a cell area. However, the I type gate is not effective particularly when securing a body in contact on the SOI substrate. In this respect, the T type gate can be effective for separating a source/drain area from a body contact area, even when a silicide layer is made a surface of the field region on the SOI substrate. However, wiring is required for putting the source area and the body on the same potential.

### SUMMARY OF INVENTION

Aspects of this invention can provide a semiconductor device including a transistor which has a gate shape capable of wirelessly connecting the source area and the body contact area, with no protrusion of the gate part to the source area side, and a semiconductor memory.

It is another aspect of this invention to provide a semiconductor device, in which an area of formation of two transistors is made small by bonding drains of the two transistors constituting a CMOS converter, and a semiconductor memory.

It is still another aspect of this invention to provide a semiconductor device, in which the bonded area of the two transistors is made smaller by permitting two kinds of impurities to be injected to an area including the drain bonded area, and a semiconductor memory.

It is a further aspect of this invention to provide a semiconductor device, which can improve soft error problems due to a-rays, 7-rays and neutrons by means of the gate shape, and a semiconductor memory.

It is a still further aspect of this invention to provide a semiconductor device, whose freedom of a position of forming a body contact in regard to each transistor on the SOI substrate is enhanced, and a semiconductor memory.

A semiconductor device according to an exemplary embodiment of this invention can have, on a field region, a transistor which includes a gate, a gate insulating film directly below the gate, a body area directly below the gate insulating film, and a source area and a drain area formed on both sides holding the body area in between. The device can include the gate consisting essentially of a first part extending along a channel width direction on the field region and a second part protruding from one end of the first part in the channel width direction to the drain area side, and being formed in an L type gate in a plan view. A body contact area can be provided on the field region on the opposite side to the first part with the second part of the L type gate in between. A low resistant layer is formed on a surface between the source area and the body contact area. This enables the source area and the body contact area to be connected without using wiring. Also, according to an exemplary semiconductor device of this invention, because a gate part does not protrude to the source region side, a distance between gates may be reduced when positioning that source area adjacent to another transistor of the same channel type as a common source area.

In a semiconductor device according to this invention, by using the L type gate, it is possible to increase the gate capacity on the second part of the area as compared to the I type gate. An increase in the gate capacity can be generally disadvantageous in terms of operating speed and power consumption. However, it is convenient in coping with problems that can be solved with a delay of a transistor operating speed. For example, it is effective for a soft error countermeasure. This is because, by delaying the transistor operation, an inverse rate of potential is relaxed when a single a ray and the like enter, and recombination time of an electric charge generated by the a ray and the like is secured prior to a complete inversion of the potential, thus contributing to preventing the potential inversion.

An exemplary semiconductor device according to this invention is able to form the field region on the SOI substrate. When using the SOI substrate, a body contact area is needed for each field region, therefore, application of this invention is highly significant. It is to be noted, however, that a semiconductor device of this invention may be applicable to a bulk substrate, so long as it has a body contact area.

This invention can include a CMOS inverter in which a p-channel and a n-channel transistor are serially connected, and the p-channel and the n-channel transistor may respectively have the L type gate. In this case, it is necessary to connect the gates of the p-channel and the n-channel transistor to each other, so that a U type gate may be formed by connecting the second parts of the two L typed gates. This invention is applicable to a semiconductor device which uses a flip-flop employing two such CMOS inverters as a memory cell.

At this point, when using the SOI substrate, it is proper for drains of the p-channel and the n-channel transistor to be bonded to each other without going through the element separation area. Since there is no well at a lower part of the drain, there will be no problem with the electrical property. Further, an area of formation of the p-channel and the n-channel transistor may be made small, thus enhancing the degree of integration.

In an area including a bonded area in which each drain of the p-channel and the n-channel transistor is bonded to each other, impurities injected to the drain area of the p-channel transistor and impurities injected to the drain area of the n-channel transistor may be mixed. When injecting from a slant direction, it is handled by retreating a mask position without widening a distance between gates. When this mask is also used when injecting impurities from a vertical direction, there will be a mixture of two kinds of impurities in the vicinity of the bonded area. Even then, there is no problem with the electrical property, while the distance between the gates may be narrowed, so that the degree of integration is enhanced.

In an area including an extension of a boundary in which the drains are bonded to each other and which is a broader area than a line width of the second part of the U type gate, no field region is formed and the element separation area may be formed. This is because the mixture of two kinds of impurities existing directly below the gate makes it possible to function as a parasitic transistor.

### BRIEF DESCRIPTION OF THE DRAWINGS

The invention will be described with reference to the accompanying drawings, wherein like numerals reference like elements, and wherein:

FIG. 1 is equivalent circuit diagram showing a memory cell of an SRAM which is an exemplary embodiment of this invention;

FIG. 2 is plan view of a field region of a memory cell shown in FIG. 1 and a gate area formed thereon;

FIG. 3 shows sectional view along the line A-A in FIG. 2;

FIG. 4 shows plan view with an impurities injection area further overlapping on FIG. 3;

FIG. 5 shows partly enlarged view of FIG. 4;

FIG. 6 shows plan view showing a layout in which four inverters are arrayed in the exemplary embodiment;

FIG. 7 shows sectional view for illustrating a problem when drains are connected to each other on a bulk substrate;

FIG. 8 (A)-FIG. 8 (D) are schedule drawings illustrating the impurities injection process for source/drain area formation;

FIG. 9 shows characteristic diagram showing the node potential in the memory cell when a single a ray enters; and

FIG. 10 shows plan view showing a single unit of transistor with the L type gate.

### DETAILED DESCRIPTION OF PREFERRED EMBODIMENTS

Exemplary embodiments according to this invention will be described below with reference to drawings.

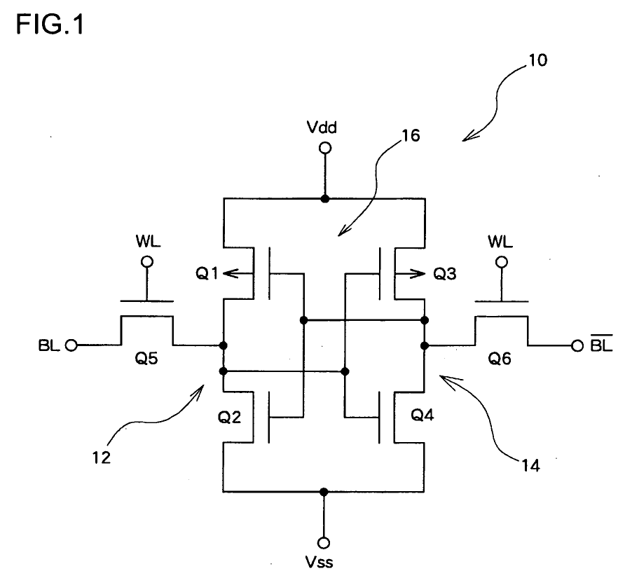

FIG. 1 is an exemplary circuit diagram of a memory cell of an SRAM which is a semiconductor device of this invention. A memory cell 10 is formed by six MOS electric field effect transistors. A first CMOS inverter 12 is formed by a p-channel load transistor Q1 and a n-channel drive transistor Q2 serially connected thereto. A second CMOS inverter 14 is formed by another p-channel load transistor Q3 and another n-channel drive transistor Q4 serially connected thereto. To a source of the two n-channel drive transistors Q2 and Q4, there is connected a Vss power supply line, while, to a source of the two n-channel drive transistors Q1 and Q3, there is connected a Vdd power supply line. And by cross coupling the first and the second inverter 12 and 14, a flip-flop 16 is formed. This flip-flop 16 is connected to a bit line BL and an inverse bit line \overline{BL} by two n-channel transfer transistors Q5 and Q6 which is turned on and off by a potential of a word line WL.

Now, in addition to the above-mentioned six MOS electric field effect transistors, the memory cell may include an additional transistor. Or the load transistors Q1 and Q3 may be formed by a load other than a transistor.

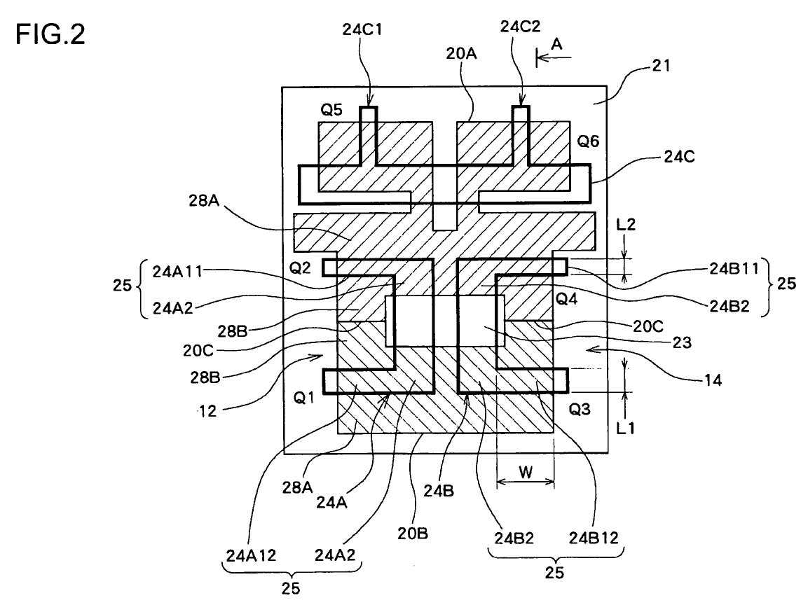

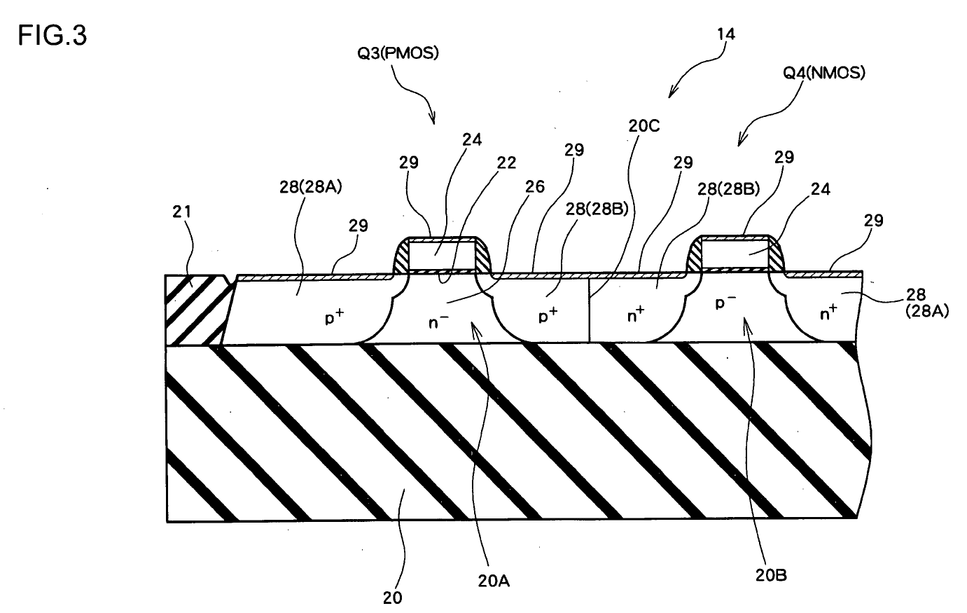

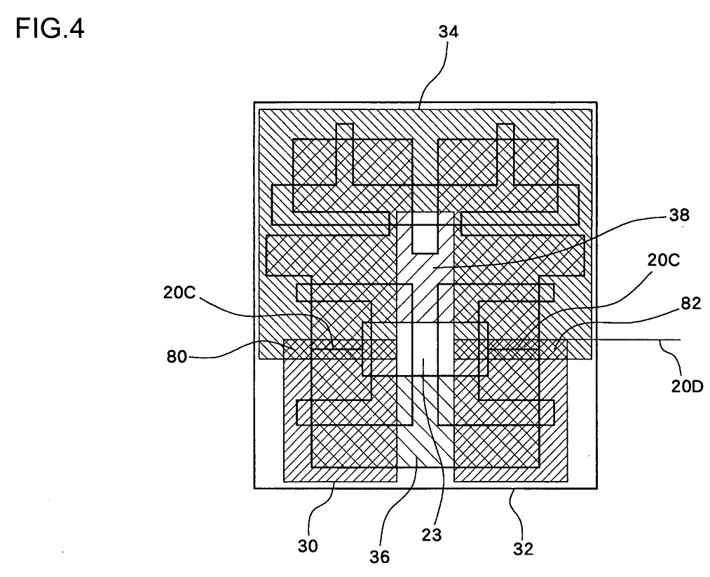

FIG. 2 is a plan view showing a field region (hatching part) of the memory cell shown in FIG. 1 and a gate area formed on that field region. FIG. 3 is a sectional view of the second CMOS inverter 14 as seen from line A-A in FIG. 3. FIG. 4 is a plan view showing an impurities injected area.

This exemplary embodiment is, as shown in FIG. 3, a semiconductor device of a SOI structure. Namely, a semiconductor layer (for example, a single crystal silicon layer) is formed on an insulating substrate 20. In this exemplary embodiment, of the six transistors Q1-Q6, there are set up a first field region 20A for the n-channel transistors Q2, Q4, Q5, and Q6 and a second field region 20B for the p-channel transistors Q1 and Q3, and these are bonded at a boundary 20C. Now, FIG. 3 shows a cross section of the second CMOS inverter 14, whereas a drain 28B of the p-channel load transistor Q3 and a drain 28B of the n-channel load transistor Q4 are bonded at the boundary 20C. Now, a p-n junction exists at this boundary 20C as FIG. 3 shows, but by making a surface of the drains 28B of both transistors Q3 and Q4 a low resistance layer 29 with silicide and the like, both transistors Q3 and Q4 are drain-connected without going through wiring. Drains 28 of the transistors Q1 and Q2 in the first CMOS inverter are bonded to each other at the boundary 20C and drain-connected by the low resistance layer 29.

A periphery of the first and the second field region 201 and 20B is, as shown in FIG. 2 and FIG. 3, insulated by, for example, an element separation film, such as an STI (Shallow Trench Isolation) 21. Also, because it is particularly an SOI structure, a lower part of each field region 20A and 20B is mutually insulated by an insulating substrate 20 such as a glass substrate, as shown in FIG. 4. Now, this invention may be applied to a bulk substrate such as silicon, insofar as the first and the second field region 20A and 20B are not bonded. The reason that it is not possible to bond the first and the second field region 20A and 20B on the bulk substrate will be described below.

Over the inside and outside of the first and the second field region 20A and 20B, gates are formed. As a sectional view of FIG. 3 shows, a gate 24 is formed through a gate insulating film 22 on the field region. Now, in this embodiment, the gate 24 is, for example, formed of a polysilicon layer. Also, a semiconductor layer directly below the gate 24 and the gate insulating film 22 shown in FIG. 3 becomes a body (may also be referred to as a channel) 26. After formation of the gate 24, using the gate 24 as a mask, impurities are injected to the semiconductor layer on both sides holding the body 26 in between, and a source/drain area 28 is formed. Further, in this exemplary embodiment, on the surface of the gate 24 and the source/drain area 28, there is formed a low resistance layer 29, such as a silicide layer. Now, on the surface of a body contact area, which is in continuity to the body 26 and exposed and which is to be described later, the low resistance layer such as the silicide layer is formed.

In FIG. 2, within a memory cell 10, there are formed three gate patterns 24A-24C. A first gate pattern 24A is a gate pattern for the load transistor Q1 and the drive transistor Q2 constituting the first CMOS inverter 12 of FIG. 1. A second gate pattern 24B is a gate pattern for the load transistor Q3 and the drive transistor Q4 constituting the second CMOS inverter 14 of FIG. 1. A third gate pattern 24C is a gate pattern for the two transfer transistors Q5 and Q6 of FIG. 1.

The first gate pattern 24A has, on the first and the second field region 20A and 20B, two first parts 24A 11 and 24A12 and a second part 24A2 extending from one end of the two first parts 24A11 and 24A12 to the drain side to form a contact area. The two first parts 24A11 and 24A12 of the first gate pattern 24A are linked by the second part 24A2. A second gate pattern 24B formed in line symmetry to the first gate pattern 24A also has the same structure as the first gate pattern 24A. Namely, the second gate pattern 24B has two first parts 24B11 and 24B12 and one second part 24B2. The third gate pattern 24C forms two T type gates 24C1 and 245C2 stretching to outside and inside the first field region.

Since the first and the second gate pattern 24A and 24B are as mentioned above, the four transistors Q1-Q4 constituting the flip-flop 16 of FIG. 1 has the following common L type gate structure. Now, the first and the second gate pattern 24A and 24B form a channel shape (U type) consisting of two L type gates 25 and 25 linked by the second part 24A2 or 24B2. By this, the gates of the p-channel and n-channel transistor constituting the first and the second CMOS inverter are connected to each other. This common gate structure will be described by taking the p-channel load transistor Q3 for an example.

A gate of this p-channel load transistor Q3 forms the L type gate 25 with the first part 24B 12 and the second part 24B2 intersecting perpendicularly to one end thereof. The first part 24B 12 functions as a transverse gate, a width L1 of the first part 24B 12 becomes a gate length, and a length W, where the first part 24B12 faces opposite to the second field region 20B, becomes a gate width. Now, the n-channel drive transistor Q4 constituting the second inverter 14, together with the p-channel load transistor Q3, by taking L2 as a channel length instead of having the same channel width W as the transistor Q3, is set at a desired current drive capacity ratio as an inverter.

In this manner, setting the transistor's capacity not by way of channel width but channel length is more advantageous in terms of layout area, because, for example, if it is a 0.18 μm process, even though the ratio of the first part's gate length L1 and L2 is, for example, increased two-fold, the minimum line width doubled will suffice.

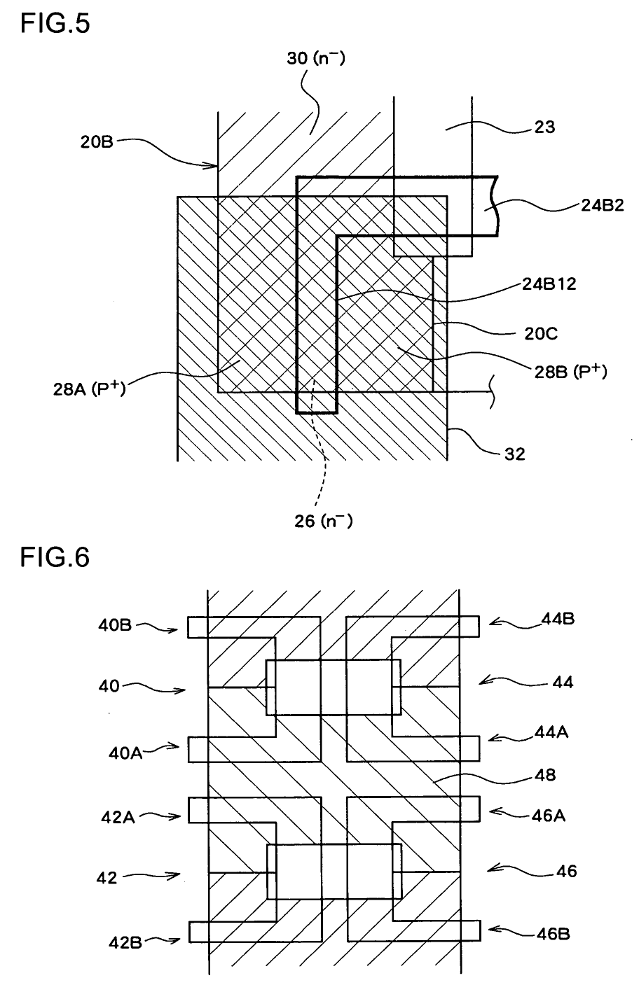

The second part 24B2 extending perpendicularly from one end of the first part 24B12 to the drain side has the following important function, in addition to being used for gate contact. On this point, description will be made referring also to FIG. 5 which is an enlarged view of the transistor Q3 part of FIG. 4.

First, for formation of a source/drain area 28, in FIG. 4, there are shown an impurities injection area 30 for the p-channel load transistor Q1, an impurities injection area 32 for the p-channel load transistor Q3, and a impurities injection area 34 for four n-channel transistors Q2, Q4-Q6.

As FIG. 5 shows the p-channel load transistor Q3 part, through injection of the impurities, the right side (boundary 20C side) of the first part 24B12 of the L type gate 25 becomes a drain area 28B of p+ and the right side becomes a source area 28A of p+.

In the case of the SOI structure such as this embodiment, the bodies 26 (refer to FIG. 3) of six transistors Q1-Q6 are mutually insulated to be in a floating condition structurally. On the other hand, potential of the body 26 is a critical factor to determine a threshold of a transistor. When the body 26 is put in the state of floating, for example, at the time of switching when source/drain areas 28 of a transfer transistor both become Vdd, the body 26 rises to the Vdd potential. Thereafter, when writing “LOW” whereby a drain of the source/drain areas 28 becomes Vss potential, positive electric charges enter the bit line BL or the inverse bit line/Blin in large quantities, so that it becomes difficult to pull them into the Vss potential (pass gate leak). Due to this pass gate leak, when “HIGH” is written into nearly all the memory cells connected to the bit line BL, a so-called light disturb occurs to make it difficult to write “LOW” in one of the memory cells. Consequently, a body contact area is needed in each field region.

In FIG. 4, impurities are not implanted to an upper side of the L type gate 25. Hence, on the second field region 20B, an area 36 on which injection of impurities for forming the source/drain area 28 is not carried out may be used as a body contact area. This is because the body contact area 36 is the same n-area as the body 26 of the p-channel load transistor Q3 shown in FIG. 3. Now, for the same reason, a body contact area 38 (p−) is secured on the first field region 20A shown in FIG. 4.

At this point, as mentioned above, the surface of the first and the second field region 20A and 20B is formed of a low resistance layer 29, such as silicide. At this time, as apparent from FIG. 5, the drain area 28B is separated from the body contact area 36 by means of the second part 24B2 of the L type gate 26, while the source area 28A and the body contact area 36 are not separated. Consequently, the body contact area 36 will be on the same potential as the source potential 28A by means of the low resistance layer 29 omitted in FIG. 4.

In this manner, since the L type gate 25 has the second part 24B2 protruding from the drain area 28B side, the source area 28A and the body contact 36 may be made to be on the same potential through the low resistance layer 29.

Referring to FIG. 6, another advantage of the second part 24B2 of the L type gate 25 not protruding to the source area 28A side will be described. That the second part 24B2 of the L type gate 25 is not protruding to the source area 28A side becomes advantageous in narrowing a transistor array pitch when placing another transistor having the source area 28A as a common source adjacent thereto.

FIG. 6 shows a plane layout of four inverters 40-46. Of the reference numerals denoting each inverter, suffix A denotes a PMOS and suffix B denotes a NMOS. PMOS40A of the inverter 20 and PMOS42A of the inverter 42 share the source area 48. Likewise, PMOS44A of the inverter 40 and PMOS46A of the inverter 46 share the source area 48. In this way, in an example of FIG. 6, the source area 48 may be shared for the four PMOS40A, 42A, 44A, and 46A, and wiring may be omitted.

Also, for the sake of the L type gate, no protrusion of the gate part exists on the source area 48 side, so that distances between the PMOS40A and 42A and between the PMOS44A and 46A may be narrowed to provide a small area. Now, when placing other NMOSs next to the NMOS40A and 44B by using the common source region, the same effect may be obtained.

Since there are many transistors of the same channel to be source-connected between themselves in this way, use of the L type gate of this exemplary embodiment as a common source area will enhance the degree of integration.

A plane layout shown in FIG. 2 can also be characterized as a structure of the first and the second CMOS inverter 12 and 14 respectively using two L type gates.

First, as shown in FIG. 6, when the L type gate is used to share the source area in placing adjacently two inverters 40 and 42 or 44 and 46, the gate part is not protruding to the common source area 48, so that the inverter's array pitch (array pitch in a longitudinal direction of FIG. 6) is narrowed, thereby enhancing the degree of integration.

Next, as shown in FIG. 2, for example, refer to the first CMOS inverter 12. Since each drain area 28B of the p-channel transistor Q1 and the n-channel transistor Q2 is directly bonded to each other without separation by an element separation film, such as STI, the array pitch is narrowed. Now, to prevent each drain area 28B of the p-channel transistor Q1 and the n-channel transistor Q2 from short circuiting between each other, a low resistance layer, such as silicide, is not formed by striding across each drain 28B.

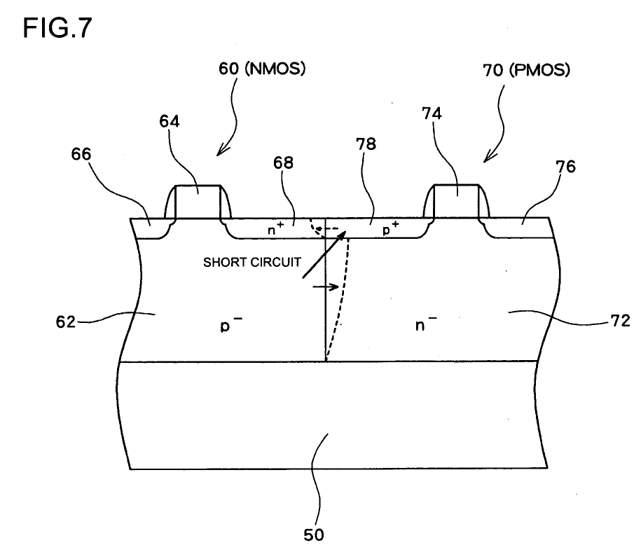

At this point, it should be understood that each drain area 28B of the p-channel transistor Q1 and the n-channel transistor Q2 need not be separated from each other through the element separation film, such as SIT, and that this is limited only to the case of the SOI structure. The reason for this will be described by referring to FIG. 7 in which the above-mentioned drain junction structure is formed on the bulk substrate.

In the SOI structure, as shown in FIG. 3, there is no well directly below the source/drain area 28 but the insulating substrate 20, such as glass. On the other hand, when the bulk substrate is used as shown in FIG. 7, a well (p−) 62 for an NMOS 60 and a well (n+) 62 for an PMOS70 are set up on a silicon substrate 50. On both sides holding in between that which is directly below a gate 64 of an NMOS60, there are provided a source area (n+−) 66 and a drain area (n+) 68. Likewise, a well (n−) 72 is provided for a PMOS70. On both sides holding in between that which is directly below a gate 74 of an NMOS60, there are provided a source area (p+−) 76 and a drain area (p+) 78. At this point, particularly, a well (p−) 62 of the NMOS60, after being subjected to heat treatment several times upon drain forming, tends to bite into the well 74 side crossing over a boundary with the well 72. Likewise, the drain (p+) 78 of the PMOS70, after being subjected to heat treatment several times upon drain forming, tends to bite into the well 68 side crossing over a boundary with the drain 68 of the NMOS60. Then, the well 62 of the NMOS60 and the drain 78 of the PMOS70 short circuit, making element separation impossible. In this respect, as mentioned above, in the case of the SOI structure, there is no well, so that there is no inconvenience as in the bulk substrate.

An area in the vicinity of the boundary 20C which will become a drain junction mentioned above is a part where the impurities injection area 30 for the PMOS and the impurities injection area for the NMOS overlap, as shown in a cross hatching part 80 of FIG. 4 in this exemplary embodiment. However, even if these different kinds of impurities are injected together, no inconvenience occurs electrically. Conversely, through formation of the area 80 to which different kinds of impurities are injected together, the array pitch of the transistors Q1 and Q2 constituting the first inverter 12 is narrowed. Now, another cross hatching part 83 of FIG. 4 is also set up to narrow the array pitch of the transistors Q3 and Q4 constituting the second inverter 14.

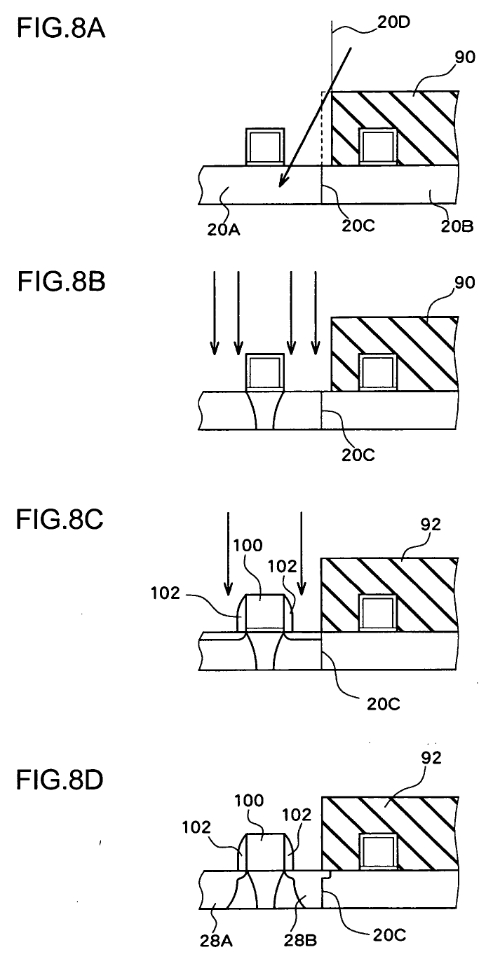

The reason therefore will be described as follows with reference to FIG. 8 (A)-FIG. 8 (D). FIG. 8 (A) shows a slant implanting (also referred to as Halo implanting) process of the impurities of the p-channel and n-channel transistor. By this process, impurities are implanted as if to penetrate to the area directly below the gate. At this time, the adjacent transistor is covered by a photoresist 90. Now, as shown in broken lines of FIG. 8 (A), when an end of the photoresist 90 is placed at a position of the boundary 20C of two transistors, an angular part of the photoresist 90 interferes with an ionic line, so that it may sometimes become impossible to implant to directly below the gate. This tendency is more pronounced as the transistors to be drain bonded become closer.

In this exemplary embodiment, instead of widening a gap between the two transistors, as shown in solid lines of FIG. 8 (A), the position of the photoresist 90 was retreated. By doing so, the angular part of the photoresist 90 shown in broken lines of FIG. 8 (A) does not exist, and the impurities may be implanted to a target position.

FIG. 8 (B) and FIG. 8 (C) show two processes to obtain an LDD (Lightly Doped Drain) structure. In the process of FIG. 8 (B), the photoresist 90 used in FIG. 8 (A) is used as is. As a result, in FIG. 8 (B), the impurities are implanted to the second field 20B over a range from the boundary 20C to the end of the photoresist 90, in addition to the first field region 20A. Conversely, when carrying out the process of FIG. 8 (B) to the second field region 20B, for the same reason, the impurities are implanted to the first field 20A crossing over the boundary 20C. In FIG. 3, the reason for occurrence of overlapping of the cross hatching part 80 where the impurities injection areas 30 and 34 overlap and the cross hatching part 82 where the impurities injection areas 32 and 34 overlap, stems from the process of FIG. 8 (B).

In FIG. 8 (C), the impurities are injected after sidewalls 102 are formed on both side walls of a gate 100. At this time, the photoresist 90 used in FIG. 8 (A) and FIG. 8 (B) has been eliminated, so that a new photoresist 92, an end part of which is positioned at the boundary 20C, is used. In this way, as shown in FIG. 8 (D), a source area 28A and a drain area 28B are formed.

At this point, bonding drains 28B to each other will not impair the electrical property, but if two kinds of impurities are injected to a field region directly below the second parts 24A2 and 24B2 of the L type gate 25 in FIG. 2, they function as a parasitic transistor.

Now, in this exemplary embodiment, as shown in FIG. 2 and FIG. 4, no field region is formed in an area 23 which includes an extension line of the boundary 90 C where the drains 28B are bonded to each other, and which is wider than the line width of the second part of the L type gate, and it is set as the element separation area such as STI.

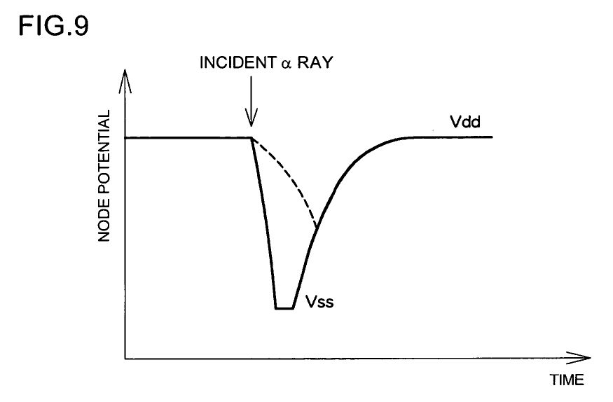

Another effect of this exemplary embodiment is that due to the L type gate structure, the gate capacity is increased to let each transistor also to have a delay function. Generally, where importance is attached to operating speed, it is preferable for gate capacity of the transistor to be small. However, for example, in the case of an SRAM, rather than the operating speed inside the memory cell 10, operating speed of its peripheral circuit is questioned. Hence, the operating speed inside the memory cell 10, for example, may be made lower than the operating speed of the I type gate which has no extra gate part. Conversely, unless the delay function is provided positively to the transistor, malfunction may occur. One example of that will be described referring to FIG. 9.

A solid line of FIG. 9 shows a change of node potential inside the memory cell 10 when an single α ray enters. When the node potential is HIGH (voltage Vdd), if the single a ray enters the transistors, it changes to LOW (Vss) for an extremely short period of time (for example, several ns/10). Thereafter, an electric charge generating in the a ray rapidly vanishes through recombination and the like, while, once the node potential is inverted, the original memory status may sometimes be inverted by the flip-flop 16. This is more pronounced as the power supply becomes lower voltage.

At this point, if the gate capacity C is increased at the L type gate of this embodiment, a delay circuit RC is formed, together with another resistant component R. In this case, as shown in a broken line in FIG. 9, it is possible to delay time for the Vss potential side to change when a single a ray enters, and during that time, a pair of electronic holes due to the a ray vanish, hence, it is possible to return to the original HIGH (Vdd) quickly.

Accordingly, for example, as in the case of a measure to counter the a ray, when capacity is increased as a countermeasure, the L type gate of this embodiment is extremely effective, because the gate capacity of the L type gate itself is large as compared to the conventional I type gate, thus making it unnecessary to form a capacity component in another part. Although the H type gate has a larger gate capacity than the L type gate, a structure of connecting a source/body contact area explained in FIG. 5 by the low resistance layer 29 is made impossible.

Now, it should be understood that this invention is not limited to the exemplary embodiment mentioned above and its various modifications are possible. For example, this invention is not restricted to what is used for the SRAM as mentioned above but likewise applicable to other transistors than the transistor for memory cell formation.

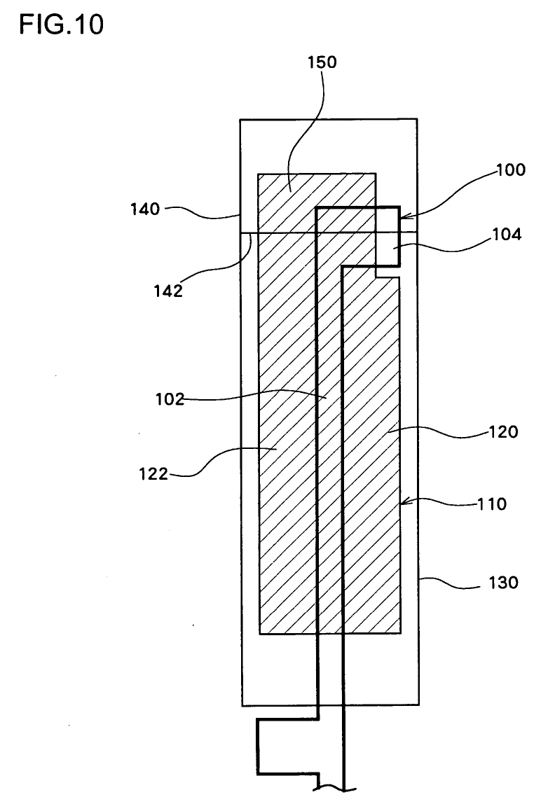

FIG. 10 shows an L type gate on a single unit of transistor. This L type gate 100 has a first part 102 extending in a longitudinal direction in FIG. 10 and a second part 104 intersecting perpendicularly to one end thereof. The first part 102 formed on a field region 110 functions as a gate. On a right side of the first part 102 held in between, there is formed a drain area 120, and on a left side, there is formed a source region 122. The second part 104 protrudes to the drain area 120 side.

A reference numeral 130 of FIG. 10 denotes an impurities injection area. To an area 140 on the upper side from a boundary position 142 on the second part 104, no impurities injection for forming the source/drain area is carried out. Therefore, the field region 110 on the upper side from the boundary line 142 may be employed as a body contact area 150. Also, as mentioned above, a surface of the source area 102 and the body contact area 150 is made into low resistance by silicide and the like, so that there is electrical continuity between the source area 102 and the body contact area 150. Even in such a single unit of transistor, the above-mentioned effect may be delivered.

Further, a semiconductor device of this invention is not limited to that which is formed on the SOI substrate, so long as there is a need for body contact, and that which is formed on a bulk substrate of a silicon substrate and the like may be acceptable. It is to be noted, however, that a connection between one drain and another is prohibited as explained in FIG. 7.

While this invention has been described in conjunction with the specific embodiments thereof, it is evident that many alternatives, modifications, and variations will be apparent to those skilled in the art. Accordingly, preferred embodiments of the invention as set forth herein are intended to be illustrative, not limiting. There are changes that may be made without departing from the spirit and scope of the invention.

1. A semiconductor device comprising, on a field region:
a transistor that includes a gate, a gate insulating film disposed below the gate, a body area disposed below the gate insulating film, and a source area and a drain area formed on both sides holding the body area in between,
the gate including a first part extending along a channel width direction on the field region and a second part protruding from one end of the first part in the channel width direction to a drain area side, and being formed in an L type gate in a plan view; and
a body contact area that is provided on the field region on an opposite side to the first part with the second part of the L type gate in between, with formation of a low resistance layer on a surface between a source area through the body contact area.

2. The semiconductor device according to claim 1, the field region being formed on an SOI (Silicon on Insulator) substrate.

3. The semiconductor device according to claim 1, further comprising:
a CMOS inverter having a p-channel and an n-channel transistor serially connected therein, and the p-channel and the n-channel transistor, respectively, having the L type gate, and a U type gate through connection of the second parts of the two L type gates.

4. The semiconductor device according to claim 3, the p-channel and the n-channel transistor being formed on an SOI substrate, each drain of the p-channel and the n-channel transistor being mutually bonded without going through an element separation area.

5. The semiconductor device according to claim 3, the p-channel and the n-channel transistor being formed on the SOI substrate, the drain of the p-channel transistor being adjacent to the drain of the n-channel transistor.

6. The semiconductor device according to claim 4, further comprising:
an area including a region on which each drain of the p-channel and the n-channel transistor are bonded to each other, and which has a mixture of impurities injected to the drain area of the p-channel and impurities injected to the drain area of the n-channel transistor.

7. The semiconductor device according to claim 6, further comprising:
the element separation area being formed on an area, which includes an extension of a boundary on which the drains are bonded to each other, and which is wider than a line width of the second part of the U type gate on which the field region is not formed.

8. The semiconductor device according to claim 1, wherein
each of two transistors of the identical channel type having the L type gate, with a common source area therebetween.

9. A semiconductor memory, comprising:
a memory cell having two CMOS inverters as a flip-flop;
each of a p-channel transistor and an n-channel transistor included in the CMOS inverters having, on the field region, a gate, a gate insulating film disposed below the gate, a body area disposed below the gate insulating film, a source area formed on one side of the body area and a drain area formed on another side of the body area;
the gate having a first part extending along a channel width direction on the field region and a second part protruding from one end of the first part in the channel width direction to the drain area side, and being formed in an L type gate in plan view;
the body contact area being provided on the field region, which is on a side opposite to the first part with the second part of the L type gate in between, with formation of a low resistance layer on a surface between the source area and the body contact area.

10. The semiconductor device according to claim 9, the field region being formed on an SOI (Silicon on Insulator) substrate.

11. The semiconductor device according to claim 9, the second parts of the two L type gates being linked to form a U type gate.

12. The semiconductor device according to claim 11, the p-channel transistor and the n-channel transistor being formed on the SOI substrate, each drain of the p-channel transistor and the n-channel transistor being bonded to each other not through an element separation region.

13. The semiconductor device according to claim 12, further comprising:
an area including an area in which each drain of the p-channel and the n-channel transistor are bonded to each other, and which has a mixture of impurities injected to the drain area of the p-channel and impurities injected to the drain area of the n-channel transistor.

14. The semiconductor device according to claim 13, further comprising:
an area that includes an extension of a boundary in which the drains are bonded to each other, and which is wider than a line width of the second part of the U type gate on which the field region is not formed, with formation of the element separation area thereon.

15. The semiconductor device according to claim 9, a channel length of the p-channel transistor being longer a channel length of the n-channel transistor.

16. The semiconductor device according to claim 15, the p-channel transistor having a same channel width as the n-channel transistor.
